(19) United States
(12) Patent Application Publication
(10) Pub. No.: US 2025/0062519 A1
(43) Pub. Date: Feb. 20, 2025

(54) ULTRA WIDEBAND BOARD-TO-BOARD TRANSITIONS FOR STRIPLINE RF TRANSMISSION LINES

(71) Applicant: Outdoor Wireless Networks LLC, Claremont, NC (US)

(72) Inventors: Fusheng LV, Suzhou, Jiangsu (CN); Ligang WU, Suzhou, Jiangsu (CN); Fan HE, Suzhou, Jiangsu (CN); Zhanming ZHANG, Suzhou, Jiangsu (CN)

(21) Appl. No.: 18/723,161

(22) PCT Filed: Jan. 13, 2022
(86) PCT No.: PCT/CN2022/071729

§ 371 Date: Jun. 21, 2024

(51) Int. Cl. H01P 3/08; H05K 1/02

(52) U.S. Cl. CPC H01P 3/08; H05K 1/0216; H05K 1/0237

(57) ABSTRACT

RF transmission lines include a first printed circuit board that includes a first stripline transmission line and a first non-stripline transmission line that is electrically connected to the first stripline transmission line. a second printed circuit board that includes a second stripline transmission line and a second non-stripline transmission line that is electrically connected to the second stripline transmission line. a metal signal trace connector that electrically connects a first signal trace of the first non-stripline transmission line to a second signal trace of the second non-stripline transmission line, and an RF shielding cover that covers the metal signal trace connector.

### FIELD

The present invention relates to communications systems and, more particularly, to transitions for stripline radio frequency (“RF”) transmission lines.

### BACKGROUND

A wide variety of printed circuit board based RF transmission lines are used in wired and wireless RF communications systems. For example, FIG. 1A is a schematic perspective view of a microstrip transmission line 10. As shown in FIG. 1A, the microstrip transmission line 10 is implemented using a so-called “single layer” printed circuit board (“PCB”) 20, which refers to a PCB that has a single dielectric substrate with a metal layer on at least one major surface thereof. As shown in FIG. 1A, the single layer printed circuit board 20 includes a dielectric substrate 22. A metal signal trace 24 is formed on an upper surface of the dielectric substrate 22. The metal signal trace 24 serves as the signal conductor or “trace” of microstrip transmission line 10. A metal ground plane 26 is formed on the lower surface of the dielectric substrate 22. The metal ground plane 26 serves as the ground conductor of the microstrip transmission line 10. RF signals can be input to microstrip transmission line 10, and the RF energy travels through the portion of the dielectric substrate 22 that is between the metal signal trace 24 and the metal ground plane 26. Microstrip transmission lines are widely used in RF communications systems. However, only the lower side of the dielectric substrate 22 is “shielded” by a ground conductor. As a result, RF energy can radiate outwardly through the edges of the dielectric substrate 22 and from the entirety of the top surface of the dielectric substrate 22 except for the portion covered by the metal signal trace 24. Such signal radiation may be significant, and tends to increase with increasing frequency of the RF signal. Thus, while microstrip transmission lines are simple and inexpensive, they may exhibit relatively high insertion losses.

FIG. 1B is a schematic perspective view of a coplanar waveguide transmission line 30, which is another type of RF transmission line. As shown in FIG. 1B, the coplanar waveguide transmission line 30 is implemented in a single layer PCB 40 that includes a dielectric substrate 42. A metal signal trace 44 and a pair of metal ground planes 45-1, 45-2 are formed on an upper surface of the dielectric substrate 42. The metal ground planes 45-1, 45-2 are separated from the metal signal trace 44 by respective small gaps in the metallization. These small gaps (where the metal is omitted) typically have unvarying widths along the length of the coplanar waveguide transmission line 30. The metal signal trace 44 serves as the signal conductor of the coplanar waveguide transmission line 30. The metal ground planes 45-1, 45-2 serve as the ground conductor of coplanar waveguide transmission line 30. RF signals can be input to coplanar waveguide transmission line 30, and the RF energy, for the most part, travels in the portion of the dielectric substrate 42 adjacent the signal trace 44 and in the air above the signal trace 44 and between the signal trace 42 and the metal ground planes 45-1, 45-2. Coplanar waveguide transmission lines may be even cheaper than microstrip transmission lines (since only one side of the dielectric substrate 42 is metallized), but tend to exhibit even higher insertion losses since only the sides of the transmission line are shielded by ground conductors.

FIG. 1C is a schematic perspective view of a grounded coplanar waveguide transmission line 50, which is another type of RF transmission line. As shown in FIG. 1C, the grounded coplanar waveguide transmission line 50 is implemented in a single layer PCB 60 that includes a dielectric substrate 62. A metal signal trace 64 and a pair of metal ground planes 65-1, 65-2 are formed on an upper surface of the dielectric substrate 62. The metal ground planes 65-1, 65-2 are separated from the metal signal trace 64 by respective small gaps in the metallization. A metal ground plane 66 is formed on the lower surface of the dielectric substrate 62. The metal signal trace 64 serves as the signal conductor of the grounded coplanar waveguide transmission line 50. The metal ground planes 65-1, 65-2 and the metal ground plane 66 serve as the ground conductor of grounded coplanar waveguide transmission line 50. A plurality of ground vias 68 extend through the dielectric substrate 62 to electrically connect the metal ground planes 65-1, 65-2 to the metal ground plane 66. The ground vias 68 may be implemented as metal plated or metal filled through holes that extend through the dielectric substrate 62. Two rows of plated through holes 68 are provided that extend through the dielectric substrate 62 on either side of the metal signal trace 64. The plated through holes 68 may be spaced apart less than ¼ of a wavelength of the RF signals that are to be transmitted over the grounded coplanar waveguide transmission line 50, which ensures that little or no RF energy may pass through the “walls” formed by the respective rows of plated through holes 68. RF signals can be input to grounded coplanar waveguide transmission line 50, and the RF energy travels through the portion of the dielectric substrate 62 that is between the metal signal trace 64 and the metal ground plane 66. The metal ground planes 65-1, 65-2, the metal ground plane 66, and the two rows of plated through holes 68 all act as grounded shielding structures that block RF energy from escaping from the dielectric substrate 62. Consequently, grounded coplanar waveguide transmission lines such as transmission line 50 may exhibit better insertion loss performance than the microstrip transmission line 10 or the coplanar waveguide transmission loss 30.

FIG. 1D is a schematic perspective view of a stripline transmission line 70, which is yet another type of RF transmission line. As shown in FIG. 1D, the stripline transmission line 10 is implemented in a multilayer PCB 80 that includes first and second dielectric substrates 82-1, 82-2. In some cases, the multilayer PCB 80 may be formed by bonding two single layer PCBs together using a material such as a dielectric prepreg layer (one of the single layer PCBs may have metal on both major surfaces thereof, while the other only has metal on an outer major surface thereof). In the depicted embodiment, a metal signal trace 84 is formed on an upper surface of the lower dielectric substrate 82-1, and a first metal ground plane 86-1 is formed on the lower surface of the lower dielectric substrate 82-1. A second metal ground plane 86-2 is formed on the upper surface of the upper dielectric substrate 82-2. While not shown in FIG. 1D, optionally, metal ground planes similar to metal ground planes 65-1, 65-2 may be formed on the upper surface of the lower dielectric substrate 82-1 to surround the metal signal trace 84, and/or rows of plated through holes that are similar to plated through holes 68 may be provided, where the plated through holes extend through both dielectric substrates 82-1, 82-2 to electrically connect the first and second metal ground planes 86-1, 86-2.

The metal signal trace 84 serves as the signal conductor of stripline transmission line 70, and the metal ground planes 86-1, 86-2 serve as the ground conductor of the stripline transmission line 70. RF signals can be input to stripline transmission line 70, and the RF energy travels through the portion of the dielectric substrate 82 that is between the metal ground planes 86-1, 86-2, which act as grounded shielding structures that block RF energy from escaping from the dielectric substrates 82-1, 82-2. Stripline transmission lines exhibit excellent insertion loss performance (even better than grounded coplanar waveguides). However, stripline transmission lines require the use of more expensive multi-layer PCBs, and are more difficult to connect to other transmission lines.

### SUMMARY

Pursuant to embodiments of the present invention, RF transmission lines are provided that include first and second PCBs. The first PCB that includes a first upper dielectric substrate, a first lower dielectric substrate, a first upper metal layer that is on an upper surface of the first upper dielectric substrate, the first upper metal layer including a first upper signal trace and a first upper ground plane, a first lower metal layer that is on a lower surface of the first lower dielectric substrate that forms a first lower ground plane, a first internal metal layer that is between the first upper dielectric substrate and the first lower dielectric substrate, the first internal metal layer including a first internal signal trace and a first internal ground plane. The second PCB includes a second dielectric substrate and a second upper metal layer that is on an upper surface of the second dielectric substrate, the second upper metal layer including a second upper signal trace. These RF transmission lines further include a metal signal trace connector that electrically connects the first upper signal trace to the second upper signal trace and an RF shielding cover that covers the metal signal trace connector.

In some embodiments, the RF shielding cover has an upper surface and at least one sidewall extending downwardly from the upper surface. In some embodiments, the second upper metal layer further comprises a second upper ground plane. In such embodiments, the RF shielding cover may be galvanically or capacitively connected to the first upper ground plane and to the second upper ground plane. The RF shielding cover, the first upper ground plane and the second upper ground plane substantially enclose the metal signal trace connector.

In some embodiments, the metal signal trace connector may be a longitudinally extending metal strip that has a first end that galvanically connects to the first upper signal trace and a second end that galvanically connects to the second upper signal trace. In other embodiments, the metal signal trace connector may be capacitively coupled to the first upper signal trace and to the second upper signal trace.

In some embodiments, the first upper signal trace comprises the signal conductor of a first stripline transmission line formed in the first printed circuit board, and the first upper ground plane and the first lower ground plane comprise the ground conductor of the first stripline transmission line. In such embodiments, the second dielectric substrate may be a second upper dielectric substrate, the second upper metal layer may further comprise a second upper ground plane, and the second printed circuit board may further include a second lower dielectric substrate, a second internal metal layer that is between the second upper dielectric substrate and the second lower dielectric substrate, the second internal metal layer including a second internal signal trace and a second internal ground plane, and a second lower metal layer that is on a lower surface of the second lower dielectric substrate that forms a second lower ground plane.

In some embodiments, the second upper signal trace may be the signal conductor of a second stripline transmission line formed in the second printed circuit board, and the second upper ground plane and the second lower ground plane may be the ground conductor of the second stripline transmission line.

In some embodiments, the RF transmission line may further include a metal ground connector that electrically connects the first lower ground plane to the second lower ground plane. The metal ground connector may, for example, be soldered to both the first lower ground plane and to the second lower ground plane.

In some embodiments, the second printed circuit board may further include a second lower metal layer that is on the lower surface of the second dielectric substrate that forms a second lower ground plane, and the second upper signal trace and the second lower ground plane may comprise the signal and ground conductors of a microstrip transmission line formed in the second printed circuit board. In some embodiments, the RF transmission line may further include a metal ground connector that electrically connects the first lower ground plane to the second lower ground plane.

In some embodiments, the second dielectric substrate is thicker than the first upper dielectric substrate and is thicker than the first lower dielectric substrate.

In other embodiments, the second printed circuit board may further include a second lower metal layer that is on the lower surface of the second dielectric substrate that forms a second lower ground plane, wherein the second upper metal layer further comprises a second upper ground plane, and the second upper signal trace comprises the signal conductor of a grounded coplanar waveguide transmission line that is formed in the second printed circuit board, and the second upper ground plane and the second lower ground plane comprise the ground conductor of the grounded coplanar waveguide transmission line. In such embodiments, the RF transmission line may further include a metal ground connector that electrically connects the first lower ground plane to the second lower ground plane and/or the second dielectric substrate may be thicker than the first upper dielectric substrate and may be thicker than the first lower dielectric substrate.

In still other embodiments, the second upper metal layer may further comprise a second upper ground plane, and the second upper signal trace may be the signal conductor of a coplanar waveguide transmission line that is formed in the second printed circuit board, and the second upper ground plane may be the ground conductor of the coplanar waveguide transmission line. The second dielectric substrate may be thicker than the first upper dielectric substrate and may be thicker than the first lower dielectric substrate.

In all of the above embodiments, the RF transmission line may further include a first conductive signal via that extends between the first internal signal trace and the first upper signal trace. Additionally, the first printed circuit board may further include first and second rows of ground vias that extend through the first upper dielectric substrate and the first lower dielectric substrate, the first and second rows of ground vias electrically connecting the first upper ground plane, the first internal ground plane, and the first lower ground plane. The first row of ground vias may be on a first side of the first internal signal trace and the second row of ground vias may be on a second side of the first internal signal trace. The first printed circuit board may also include a first additional dielectric layer that is interposed between the first upper dielectric substrate and the first lower dielectric substrate. In some embodiments, the first upper ground plane may surround the first upper signal trace on at least three sides.

Pursuant to further embodiments of the present invention, RF transmission lines are provided that include a first printed circuit board that includes a first stripline transmission line and a first non-stripline transmission line that is electrically connected to the first stripline transmission line, a second printed circuit board that includes a second stripline transmission line and a second non-stripline transmission line that is electrically connected to the second stripline transmission line, a metal signal trace connector that electrically connects a first signal trace of the first non-stripline transmission line to a second signal trace of the second non-stripline transmission line, and an RF shielding cover that covers the metal signal trace connector.

In some embodiments, the first non-stripline transmission line may be a microstrip transmission line, a coplanar waveguide transmission line, or a grounded coplanar waveguide transmission line.

In some embodiments, the RF shielding cover may have an upper surface and at least one sidewall extending downwardly from the upper surface. The RF shielding cover may be soldered to a first upper ground plane of the first stripline transmission line and to a second upper ground plane of the second stripline transmission line. The RF shielding cover, the first upper ground plane and the second upper ground plane may substantially enclose the metal signal trace connector.

In some embodiments, the metal signal trace connector may be a longitudinally extending metal strip that has a first end that galvanically connects to the first signal trace and a second end that galvanically connects to the second signal trace. In other embodiments, the metal signal trace connector may be capacitively coupled to the first signal trace and to the second signal trace.

In some embodiments, the first stripline transmission line may include a first upper ground plane and a first lower ground plane, and the second stripline transmission line may include a second upper ground plane and a second lower ground plane. The RF transmission line may further include a metal ground connector that electrically connects the first lower ground plane to the second lower ground plane. The metal ground connector may be soldered to both the first lower ground plane and to the second lower ground plane.

In some embodiments, the RF transmission line may further comprise a first conductive signal via that extends between a signal trace of the first stripline transmission line and the first signal trace of the first non-stripline transmission line.

### BRIEF DESCRIPTION OF THE DRAWINGS

FIG. 1A is a schematic perspective view of a conventional microstrip transmission line.

FIG. 1B is a schematic perspective view of a conventional coplanar waveguide transmission line.

FIG. 1C is a schematic perspective view of a conventional grounded coplanar waveguide transmission line.

FIG. 1D is a schematic perspective view of a conventional stripline transmission line.

FIG. 2A is a schematic top perspective view of an RF transmission line according to embodiments of the present invention that includes a pair of stripline transmission lines that are connected using a stripline transition.

FIG. 2B is a schematic bottom perspective view of the RF transmission line of FIG. 2A.

FIG. 2C is a schematic partially exploded top perspective view of the RF transmission line of FIG. 2A.

FIG. 2D is a schematic fully exploded side perspective view of the RF transmission line of FIG. 2A.

FIG. 3A is a graph of the simulated return loss performance of the RF transmission line of FIG. 2A.

FIG. 3B is a graph of the simulated insertion loss performance of the RF transmission line of FIG. 2A.

FIG. 4A is a schematic side perspective view of an RF transmission line according to embodiments of the present invention that includes a stripline transmission line and a coplanar waveguide transmission line that are connected using a stripline-to-coplanar waveguide transition.

FIG. 4B is a schematic side perspective view of an RF transmission line according to embodiments of the present invention that includes a stripline transmission line and a grounded coplanar waveguide transmission line that are connected using a stripline-to-grounded coplanar waveguide transition.

FIG. 4C is a schematic side perspective view of an RF transmission line according to embodiments of the present invention that includes a stripline transmission line and a microstrip transmission line that are connected using a stripline-to-microstrip transition.

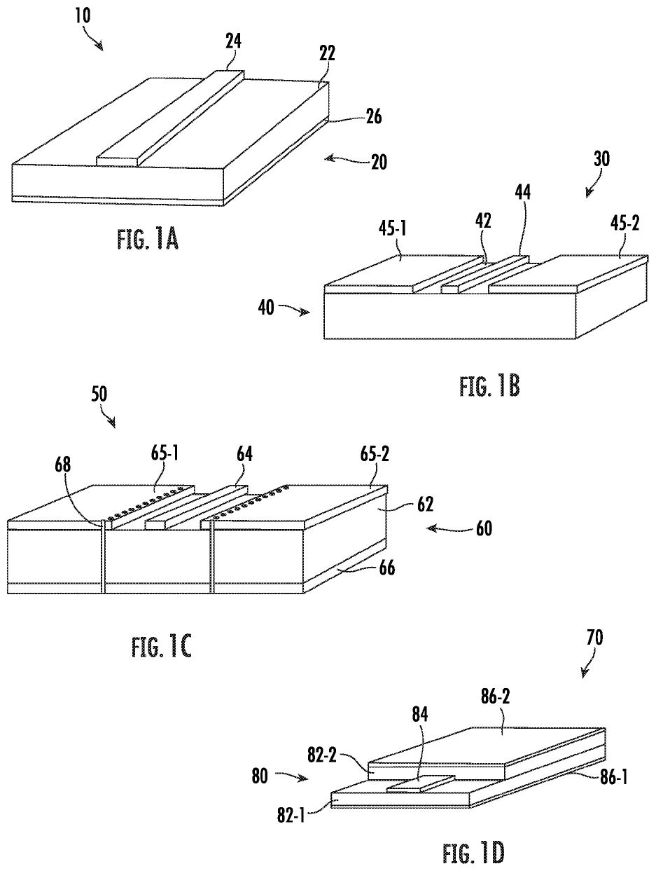

In this specification, like reference numerals will be used to refer to like elements. When multiple of the same element are included in certain of the embodiments disclosed herein, they may be referred to by two-part reference numerals that include two numbers separated by a hyphen (e.g., 20-1). Such elements may be referred to individually by their full reference numeral and collectively by the first part of their reference numeral.

### DETAILED DESCRIPTION

While stripline transmission lines may exhibit very low transmission losses, they are also expensive to implement. RF PCBs are significantly more expensive than standard PCBs, and strip line transmission lines require multilayer PCB structures that further increase both material and manufacturing costs. Thus, in many cases it is impractical to implement an entire communication system in a multilayer PCB structure to allow for the use of stripline transmission lines. Additionally, in many applications, certain components may be used in many different communication systems. For example, base station antennas include numerous PCB-based circuit components such as electromechanical phase shifters, calibration circuits, hybrid couplers, power dividers and the like that include RF transmission lines. The same circuit components (e.g., a particular phase shifter assembly) may be used in many different antenna designs. As a result, it is advantageous to implement these circuit components as standalone elements that are formed on their own PCBs so that the circuit components can readily be used in different antennas.

In communications systems where different PCB-based circuit components are formed on separate PCBs, it becomes necessary to interconnect transmission lines on the different PCBs. Conventionally, such connections are often implemented using cables such as coaxial cables. While coaxial cables can readily be connected to microstrip, coplanar waveguide and ground coplanar waveguide transmission lines, it is more difficult to connect a coaxial cable to a stripline transmission line as the signal trace is embedded between two dielectric substrates and ground planes and only exposed at the edges of the multilayer PCB. Additionally, coaxial cable connections are labor intensive to implement, and the solder joints between the coaxial cables and the PCB-based transmission lines may be potential source of passive intermodulation distortion, particularly if forces are applied to the cables after the solder joints are formed.

Pursuant to embodiments of the present invention, various RF transmission line transitions are provided that can be used to connect an RF transmission line implemented in a first PCB to an RF transmission line implemented in a second PCB. The RF transmission line transitions according to embodiments of the present invention may include, for example, stripline-to-stripline transitions, stripline-to-coplanar waveguide transitions, stripline-to-grounded coplanar waveguide transitions, and stripline-to-microstrip transitions. These transitions may be used to form RF transmission lines that span two (or more) printed circuit boards.

In one example embodiment, an RF transmission line is provided that includes a stripline-to-stripline transition. The RF transmission line spans first and second PCBs, each of which have a stripline transmission line implemented therein. Each PCB includes one or more conductive signal vias that electrically connect the signal trace of the respective stripline transmission line to a respective auxiliary signal trace that is formed in the top metal layer of the respective PCB. Each auxiliary signal trace may be a signal trace of a non-stripline transmission line such as a signal trace of (1) a coplanar waveguide transmission line, (2) a grounded coplanar waveguide transmission line or (3) a microstrip transmission line. The metal ground planes of the top metal layer of each printed circuit board are separated from the auxiliary signal traces and conductive signal vias by gaps in the metallization. A first end of a metal signal trace connector may be soldered or otherwise electrically connected to the first auxiliary signal trace and a second end of the metal signal trace connector may be soldered or otherwise electrically connected to the second auxiliary signal trace in order to electrically connect the auxiliary signal trace of the first PCB to the auxiliary signal trace of the second PCB. An RF shielding cover may be provided that covers the two auxiliary signal traces and the metal signal trace connector without contacting the auxiliary signal traces or the metal signal trace connector. The RF shielding cover may be soldered to the metal ground planes of the top metal layer of each printed circuit board, thereby electrically connecting the metal ground plane on the first PCB to the metal ground plane on the second PCB. The RF transmission line may optionally include a metal ground connector that electrically connects the metal ground plane on the bottom surface of the first PCB to the metal ground plane on the bottom surface of the second PCB.

In other example embodiments, RF transmission lines are provided in which a first PCB that includes a stripline transmission line is connected to a second PCB that includes a coplanar waveguide transmission line, a grounded coplanar waveguide transmission line, or a microstrip transmission line using similar transition elements.

Thus, according to some embodiments of the present invention, RF transmission lines are provided that include first and second PCBs. The first PCB that includes a first upper dielectric substrate, a first lower dielectric substrate, a first upper metal layer that is on an upper surface of the first upper dielectric substrate, the first upper metal layer including a first upper signal trace and a first upper ground plane, a first lower metal layer that is on a lower surface of the first lower dielectric substrate that forms a first lower ground plane, a first internal metal layer that is between the first upper dielectric substrate and the first lower dielectric substrate, the first internal metal layer including a first internal signal trace and a first internal ground plane. The second PCB includes a second dielectric substrate and a second upper metal layer that is on an upper surface of the second dielectric substrate, the second upper metal layer including a second upper signal trace. These RF transmission lines further include a metal signal trace connector that electrically connects the first upper signal trace to the second upper signal trace and an RF shielding cover that covers the metal signal trace connector.

In other embodiments, RF transmission lines are provided that include a first printed circuit board that includes a first stripline transmission line and a first non-stripline transmission line that is electrically connected to the first stripline transmission line, a second printed circuit board that includes a second stripline transmission line and a second non-stripline transmission line that is electrically connected to the second stripline transmission line, a metal signal trace connector that electrically connects a first signal trace of the first non-stripline transmission line to a second signal trace of the second non-stripline transmission line, and an RF shielding cover that covers the metal signal trace connector.

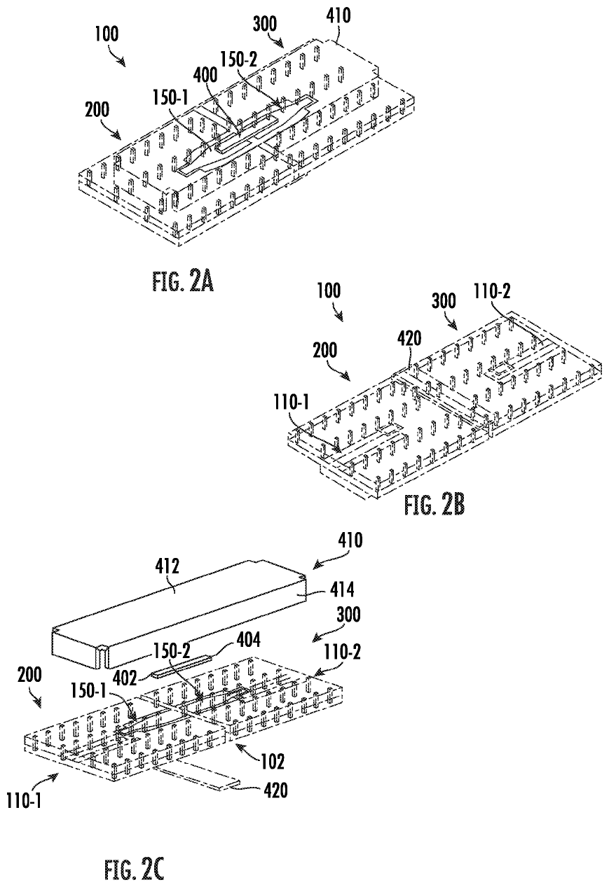

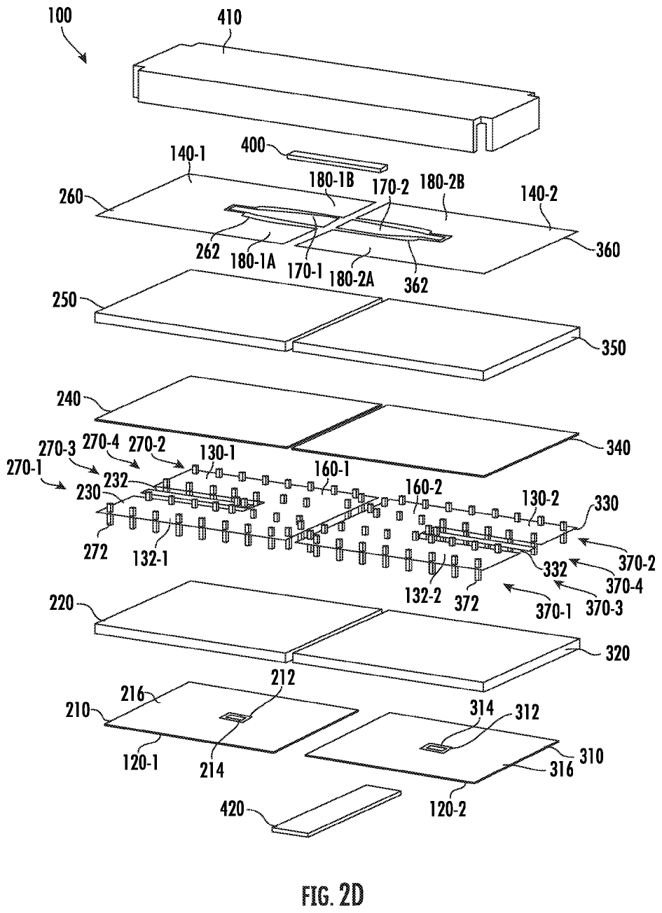

Embodiments of the present invention will now be discussed in further detail with reference to FIGS. 2A-4C.

FIGS. 2A-2D illustrate an RF transmission line according to embodiments of the present invention. In particular, FIGS. 2A and 2B are schematic top and bottom perspective views of an RF transmission line 100 according to embodiments of the present invention that includes a pair of stripline transmission lines that are connected using a stripline-to-stripline transition. FIG. 2C is a schematic partially exploded top perspective view of the RF transmission line 100, and FIG. 2D is a schematic fully exploded side perspective view thereof.

Referring to FIGS. 2A-2D, the RF transmission line 100 comprises a first printed circuit board 200 and a second printed circuit board 300, each of which are multilayer printed circuit boards. The first and second printed circuit boards 200, 300 are separated by a gap 102 (see FIG. 2C). As shown best in FIG. 2D, the first printed circuit board 200 includes a first lower dielectric substrate 220 and a first upper dielectric substrate 250. The first lower dielectric substrate 220 and the first upper dielectric substrate 250 may each comprise standard RF printed circuit board materials such as, for example, Taconic TSM-DS3, Arlon AD3003A, or Rogers RO3003 printed circuit board substrate materials. A first lower metal layer 210 is formed on the lower surface of the first lower dielectric substrate 210 and a first upper metal layer 260 is formed on the upper surface of the first upper dielectric substrate 250. A first interlayer metal layer 230 is formed on the upper surface of the first lower dielectric substrate 220. A first additional dielectric layer 240 is positioned between the first interlayer metal layer 230 and the first upper dielectric substrate 250.

The first additional dielectric layer 240 may be used to adhere the upper portion of the first printed circuit board 200 to the lower portion of the first printed circuit board 200. The first additional dielectric layer 240 may be formed using any suitable dielectric material such as, for example, a so-called “prepreg” material such as a fiberglass material or other composite fiber material that is pre-impregnated with a thermoset polymer matrix material (e.g., an epoxy resin). The composite fiber material may take the form of a weave. The epoxy resin (or other thermoset polymer matrix material) typically has adhesive properties, and a curing agent is included in the prepreg material. The prepreg material becomes flowable when heated and then acts as an adhesive to bind the fibers together and to other components that contact the major surfaces of the prepreg layer. While in the depicted embodiment, the first interlayer metal layer 230 is between the first lower dielectric substrate 220 and the first additional dielectric layer 240, it will be appreciated that in other embodiments the first interlayer metal layer 230 may instead be between the first upper dielectric substrate 250 and the first additional dielectric layer 240, and the first additional dielectric layer 240 may directly contact the upper surface of the first lower dielectric substrate 220.

First through fourth rows 270-1 through 272-4 of first ground vias 272 extend through the first lower dielectric substrate 220, the first interlayer metal layer 230, the first additional dielectric layer 240, and the first upper dielectric substrate 250. The first ground vias 272 may each electrically interconnect portions of the first lower metal layer 220, the first interlayer metal layer 230 and the first upper metal layer 260. The first and second rows 270-1, 270-2 of first ground vias 272 may extend along opposed outer edges of the first printed circuit board 200 in some embodiments. The third and fourth rows 270-3, 270-4 of first ground vias 272 may extend between the first and second rows 270-1, 270-2 of first ground vias 272. The ground vias 272 in each of the first through fourth rows 270-1 through 270-4 may be spaced apart from each other by less than a quarter wavelength of a lowest frequency in an operating frequency range of the RF transmission line 100. With this spacing, the ground vias 272 act as sidewalls of a waveguide structure and thus constrain the RF energy from travelling laterally beyond the ground vias 272

A first stripline transmission line 110-1 and a first non-stripline transmission line 150-1 are formed in the first printed circuit board 200. The first stripline transmission line 110-1 comprises a first lower metal ground plane 120-1, a first metal signal trace 130-1, and a first upper metal ground plane 140-1. The first lower metal ground plane 120-1 is formed in the first lower metal layer 210, the first metal signal trace 130-1 is formed in the first interlayer metal layer 230, and the first upper metal ground plane 140-1 is formed in the first upper metal layer 260. A first interlayer ground plane 132-1 may optionally be formed in the first interlayer metal layer 230 that surrounds the first metal signal trace 130-1 on three sides thereof. A gap 232 in the first interlayer metal layer 230 isolates the first metal signal trace 130-1 from the first interlayer ground plane 132-1.

The first non-stripline transmission line 150-1 is implemented as a grounded coplanar waveguide transmission line 150-1. The grounded coplanar waveguide transmission line 150-1 comprises a first lower metal ground plane 160-1, a first non-stripline metal signal trace 170-1, and a pair of first upper metal ground planes 180-1A, 180-1B. The first lower metal ground plane 160-1 is formed in the first intermetal metal layer 230, the first non-stripline metal signal trace 170-1 is formed in the first upper metal layer 260, and the first upper metal ground planes 180-1A, 180-1B are also formed in the first upper metal layer 260. In particular, the first upper metal ground plane 140-1 extends in the first upper metal layer 260 toward the second printed circuit board 300, thereby forming the pair of first upper metal ground planes 180-1A, 180-1B. A gap 262 in the first upper metal layer 260 isolates the first metal signal trace 170-1 from the first upper metal ground planes 180-1A, 180-1B and the first metal ground planes 140-1.

The first through fourth rows 270-1 through 270-4 of first ground vias 272 provide RF shielding for both the first stripline transmission line 110-1 and the first non-stripline transmission line 150-1. One or more first conductive signal vias 280 extend through the first lower dielectric substrate 220, the first interlayer metal layer 230, the first additional dielectric layer 240, and the first upper dielectric substrate 250. The first conductive signal vias 280 electrically connect the first metal signal trace 130-1 of the first stripline transmission line 110-1 to the first non-stripline metal signal trace 170-1 of the first non-stripline transmission line 150-1. A gap 212 is formed in the first lower metal layer 210 that separates the metallization into a small first inner metallization 214 that is surrounded by a much larger first outer metallization 216. The first outer metallization 216 forms the first lower metal ground plane 120-1. The first conductive signal vias 280 extend through the first lower dielectric substrate 220 to electrically connect to the first inner metallization 214. The first inner metallization 214 and the gap 212 are provided to electrically isolate the first conductive signal vias 280 from the first lower metal ground plane 120-1.

The first ground vias 272 and the first conductive signal vias 280 may be metal-plated or metal-filled vias. Note that in FIG. 2D the openings in the first and second lower dielectric substrates 220, 320, the first and second additional dielectric substrates 240, 340, and the first and second upper dielectric substrates 250, 350 through which the ground vias 272 and conductive signal vias 280 extend are not shown to simplify the drawing.

As FIGS. 2A-2D and the above description makes clear, the first stripline transmission line 110-1 is formed in the left side of the first printed circuit board 200 and the first non-stripline transmission line 150-1 is formed in the right side of the first printed circuit board 100. The first conductive signal vias 280 electrically connect the first stripline transmission line 110-1 to the first non-stripline transmission line 150-1. As described below, by transitioning from a stripline transmission line to a non-stripline transmission line, the metal signal trace is brought to a top surface of the first printed circuit board 200 where it can more readily be electrically connected to a metal signal trace of the second printed circuit board 300.

The second printed circuit board 300 has the same general construction as the first printed circuit board 200, and like components may be identical in the two printed circuit boards 200, 300. Thus, the second printed circuit board 300 includes a second lower dielectric substrate 320, a second upper dielectric substrate 350, a second lower metal layer 310 that is formed on the lower surface of the second lower dielectric substrate 310, a second upper metal layer 360 is formed on the upper surface of the second upper dielectric substrate 350, and a second interlayer metal layer 330 and a second additional dielectric layer 340 are formed between the upper surface of the second lower dielectric substrate 320 and the lower surface of the second upper dielectric substrate 350. First through fourth rows 370-1 through 370-4 of second ground vias 372 extend through the second lower dielectric substrate 320, the second interlayer metal layer 330, the second additional dielectric layer 340, and the second upper dielectric substrate 350. The second ground vias 372 may be identical in shape and position to the first ground vias 272 and hence further description thereof is omitted.

A second stripline transmission line 110-2 and a second non-stripline transmission line 150-1 are formed in the second printed circuit board 300. The second stripline transmission line 110-2 comprises a second lower metal ground plane 120-2, a second metal signal trace 130-2, and a second upper metal ground plane 140-2. The second lower metal ground plane 120-2 is formed in the second lower metal layer 310, the second metal signal trace 130-2 is formed in the second interlayer metal layer 330, and the second upper metal ground plane 140-2 is formed in the second upper metal layer 360. A second interlayer ground plane 132-2 may optionally be formed in the second interlayer metal layer 330 that surrounds the second metal signal trace 130-2 on three sides thereof. A gap 332 in the second interlayer metal layer 330 isolates the second metal signal trace 130-2 from the second interlayer ground plane 132-2.

The second non-stripline transmission line 150-2 is implemented as a grounded coplanar waveguide transmission line 150-2 that comprises a second lower metal ground plane 160-2, a second non-stripline metal signal trace 170-2, and a pair of second upper metal ground planes 180-2A, 180-2B. The second lower metal ground plane 160-2 is formed in the second intermetal metal layer 330, the second non-stripline metal signal trace 170-2 is formed in the second upper metal layer 360, and the second upper metal ground planes 180-2A, 180-2B are also formed in the second upper metal layer 360. A gap 362 in the second upper metal layer 360 isolates the second metal signal trace 170-2 from the second upper metal ground planes 180-2A, 180-2B and the second metal ground planes 140-2.

The first through fourth rows 370-1 through 370-4 of first ground vias 372 provide RF shielding for both the second stripline transmission line 110-2 and the second non-stripline transmission line 150-2. One or more second conductive signal vias 380 extend through the second lower dielectric substrate 320, the second interlayer metal layer 330, the second additional dielectric layer 340, and the second upper dielectric substrate 350. The second conductive signal vias 380 electrically connect the second metal signal trace 130-2 of the second stripline transmission line 110-2 to the second non-stripline metal signal trace 170-2 of the second non-stripline transmission line 150-2. A gap 312 is formed in the second lower metal layer 310 that separates the metallization into a small second inner metallization 314 that is surrounded by a much larger second outer metallization 316. The second outer metallization 316 forms the second lower metal ground plane 120-2. The second conductive signal vias 380 extend through the second lower dielectric substrate 320 to electrically connect to the second inner metallization 314. The second inner metallization 314 and the gap 312 are provided to electrically isolate the second conductive signal vias 380 from the second lower metal ground plane 120-2. The second ground vias 372 and the second conductive signal vias 380 may be metal-plated or metal-filled vias.

As FIGS. 2A-2D and the above description makes clear, the first stripline transmission line 110-1 is formed in the left side of the first printed circuit board 200 and the first non-stripline transmission line 150-1 is formed in the right side of the first printed circuit board 100. The first conductive signal vias 280 electrically connect the first stripline transmission line 110-1 to the first non-stripline transmission line 150-1. As described below, by transitioning from a stripline transmission line to a non-stripline transmission line, the metal signal trace is brought to a top surface of the first printed circuit board 200 where it can more readily be electrically connected to a metal signal trace of the second printed circuit board 300.

The RF transmission line 100 further includes a metal signal trace connector 400, an RF shield 410, and a metal ground connector 420. The metal signal trace connector 400 may comprise a strip of metal (e.g., sheet metal) that has a first end 402 and a second end 404. The first end 402 of metal signal trace connector 400 may be soldered to the first non-stripline metal signal trace 170-1, and the second end 404 of metal signal trace connector 400 may be soldered to the second non-stripline metal signal trace 170-2, thereby providing an electrical connection therebetween. The metal signal trace connector 400 may span the gap 102 between the first printed circuit board 200 and the second printed circuit board 300.

Referring to FIG. 2C, the RF shield 410 may comprise, for example, an open box-shaped structure. The RF shield 410 may be formed of cut and bent sheet metal. The RF shield 410 in the illustrated embodiment has an upper surface 412 and a plurality of sidewalls 414 extending downwardly from the upper surface 412. The RF shield may be soldered to the first upper metal ground plane 140-1 and to the second upper metal ground plane 140-2, thereby providing an electrical connection therebetween to provide a continuous ground reference between the first stripline transmission line 110-1 and the first non-stripline transmission line 170-1 on the one hand and second stripline transmission line 110-2 and the second non-stripline transmission line 170-2 on the other hand. The RF shield 410 also covers the metal signal trace connector 400 and in conjunction with the first and second metal layers 260, 360, substantially encloses the metal signal trace connector 400.

The metal ground connector 420 may comprise a strip of metal (e.g., sheet metal) that may be soldered to the first lower metal ground plane 120-1 and to the second lower metal ground plane 120-2, thereby providing an electrical connection therebetween. While the first and second lower metal ground planes 120-1, 120-2 are electrically connected through the RF shield 410 and the ground vias 272, 372, the more direct electrical connection through the metal ground connector 420 may provide improved transmission stability. The metal ground connector 420 may span the gap 102 between the first printed circuit board 200 and the second printed circuit board 300.

An additional advantage of the RF transmission line 100 is that the transmission line includes signal traces 170-1, 170-2 that are at the topmost metal layers of the multilayer printed circuit boards 200, 300. When the RF transmission line 100 is used in a larger system (e.g., in a base station antenna), a prototype antenna may be fabricated. In many instances, the return loss of the prototype antenna may not be satisfactory. When this occurs, the RF shield 410 may be removed and characteristics of the metal signal trace connector 400 such as its width, thickness, connection points to the signal traces 170-1, 170-2, etc. may be changed to vary and hopefully improve the return loss performance. Once the return loss performance is acceptable, then production antennas may be manufactured based on the design of the metal signal trace connector 400 that provides acceptable return loss performance.

It will be appreciated that FIGS. 2A-2D may only show a portion of the first and second printed circuit boards 200, 300. As FIGS. 2A-2D clearly show, the various metal “layers” (e.g., layers 210, 230, 260, 310, 330, 360) may be patterned metal layers that are not continuous layers, but instead have portions where no metal is present. Each patterned metal layer may be formed, for example, by depositing a continuous metal layer on a surface (i.e., upper or lower) of a dielectric substrate, forming a mask on the continuous metal layer and then etching the continuous metal layer using the mask as an etch mask to form the patterned metal layer. Dielectric material may optionally be filled into the openings in the patterned metal layers, but more typically the gaps are simply filled with air. a patterned metal layer abuts a prepreg layer, the prepreg material may fill the openings in the patterned metal layer.

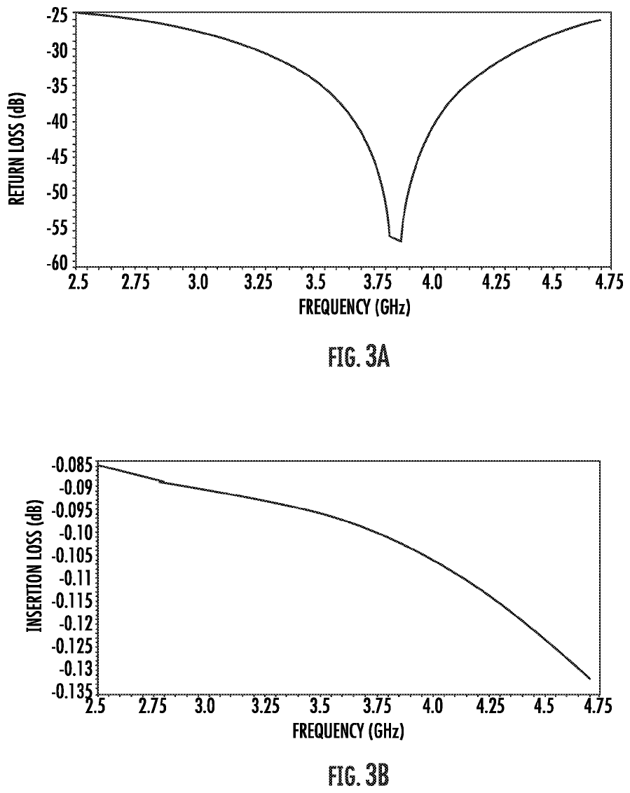

FIGS. 3A and 3B are graphs illustrating the simulated return loss and insertion loss performance, respectively, of the RF transmission line 100. As shown in FIG. 3A, the return loss is less than −25 dB in the range from 2.5 GHz through about 4.75 GHz, which is 47% of the bandwidth. This demonstrates that the RF transmission line 100 is an ultra-wideband transmission line. As shown in FIG. 3B, the insertion loss is less 0.13 dB over the range of 2.5-4.75 GHz.

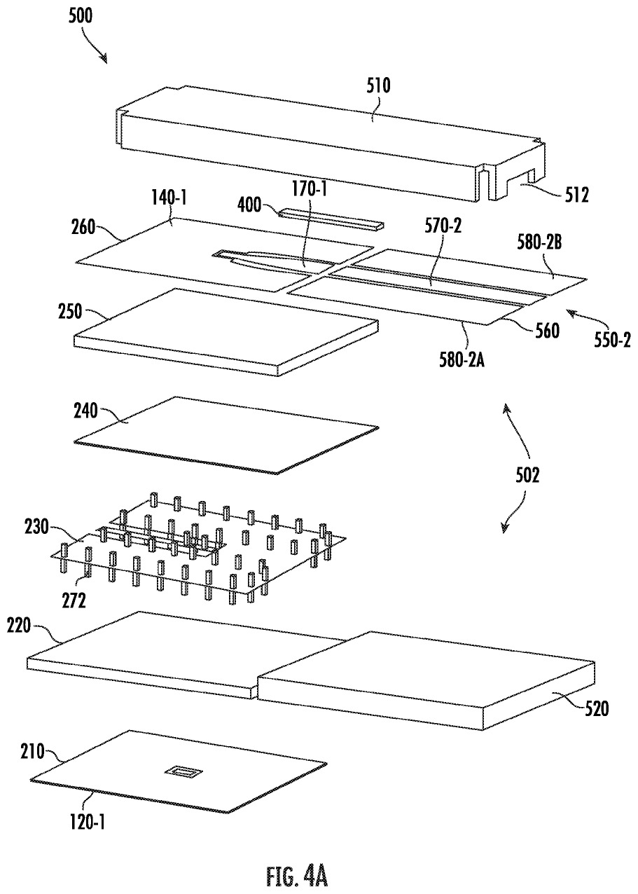

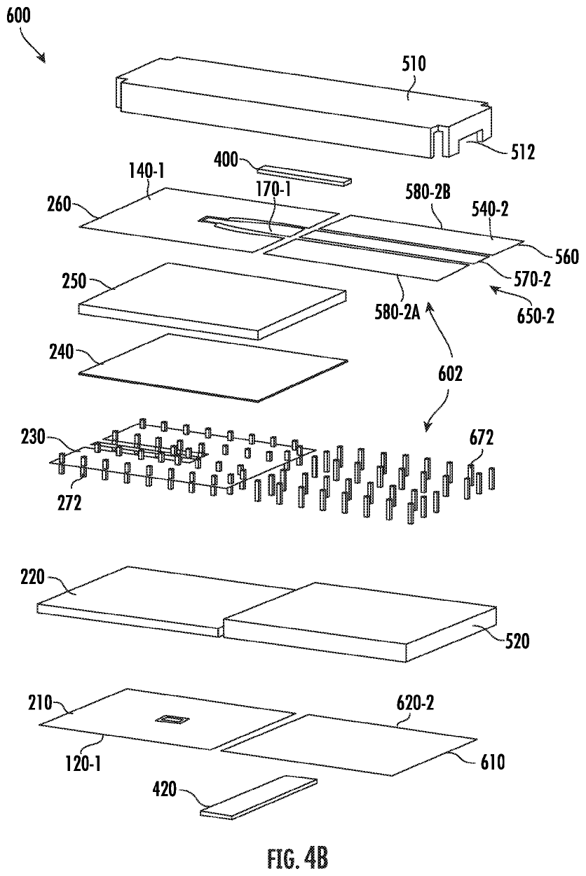

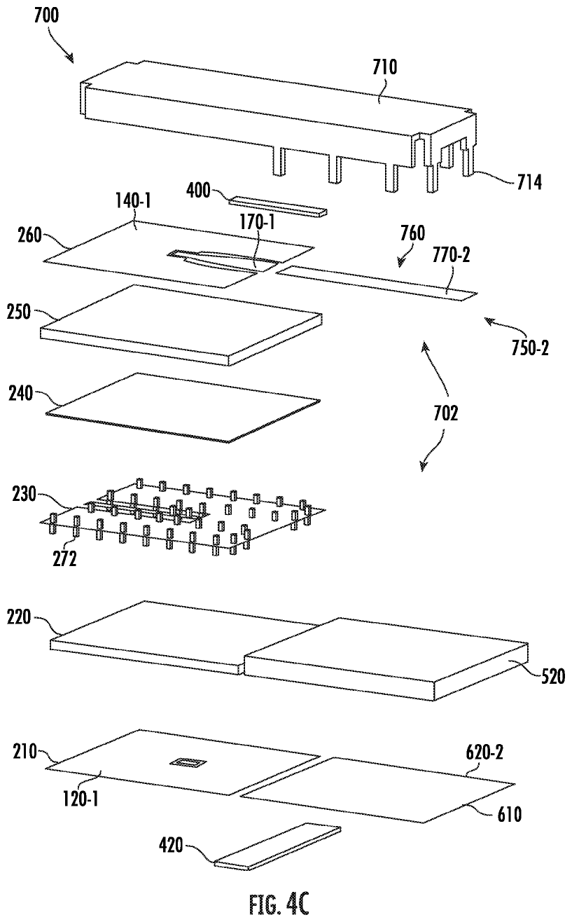

FIG. 4A is a schematic side perspective view of an RF transmission line 500 according to embodiments of the present invention that includes a stripline transmission line and a coplanar waveguide transmission line that are connected using a stripline-to-coplanar waveguide transition. RF transmission line 500 includes the first printed circuit board of RF transmission line 100 that has the first stripline transmission line 110-1 and the first non-stripline transmission line 150-1. As these structures/elements have already been described above, further description thereof will be omitted.

As shown in FIG. 4A, RF transmission line 500 further includes a second printed circuit board 502 that has a dielectric substrate 520 and a second upper metallization layer 560 formed on an upper surface of the dielectric substrate 520. A second non-stripline transmission line 550-2 is formed in the second printed circuit board 502. The second non-stripline transmission line 550-2 is implemented as a coplanar waveguide transmission line 550-2. The coplanar waveguide transmission line 550-2 includes a second non-stripline metal signal trace 570-2 and a pair of second upper metal ground planes 580-2A, 580-2B. The second non-stripline metal signal trace 570-2 and the second upper metal ground planes 580-2A, 580-2B are formed in the second upper metal layer 560. The RF transmission line 500 also includes the metal signal trace connector 400 and an RF shield 510 that is similar to RF shield 410. RF shield 510, however, includes a cutout 512 in one sidewall that ensures that the RF shield does not short circuit to second non-stripline metal signal trace 570-2.

FIG. 4B is a schematic side perspective view of an RF transmission line 600 according to embodiments of the present invention that includes a stripline transmission line and a grounded coplanar waveguide transmission line that are connected using a stripline-to-grounded coplanar waveguide transition. RF transmission line 600 includes the first printed circuit board of RF transmission line 100 that has the first stripline transmission line 110-1 and the first non-stripline transmission line 150-1. As these structures/elements have already been described above, further description thereof will be omitted.

As shown in FIG. 4B, RF transmission line 600 is very similar to RF transmission line 500, except that RF transmission line 600 is a grounded coplanar waveguide transmission line such that coplanar waveguide transmission line 550-2 of RF transmission line 500 is replaced in RF transmission line 600 with a grounded coplanar waveguide transmission line 650-2. Accordingly, RF transmission line 600 further includes a second printed circuit board 602 that is similar to second printed circuit board 502, but further includes a second lower metallization layer 610 on a lower surface of dielectric substrate 520 which forms a second lower metal ground plane 620-2. Additionally, a plurality of ground vias 672 electrically connect the second upper metal ground planes 580-2A, 580-2B to the second lower metal ground plane 620-2. The RF transmission line 600 also includes the metal signal trace connector 400, the RF shield 510, and the metal ground connector 420.

FIG. 4C is a schematic side perspective view of an RF transmission line 700 according to embodiments of the present invention that includes a stripline transmission line and a microstrip transmission line that are connected using a stripline-to-microstrip transition. RF transmission line 500 includes the first printed circuit board of RF transmission line 100 that has the first stripline transmission line 110-1 and the first non-stripline transmission line 150-1. As these structures/elements have already been described above, further description thereof will be omitted.

As shown in FIG. 4C, RF transmission line 700 further includes a second printed circuit board 702 that has a dielectric substrate 520, a second upper metallization layer 760 formed on an upper surface of the dielectric substrate 520, and a second lower metallization layer 760 formed on a lower surface of the dielectric substrate 520. A second non-stripline transmission line 750-2 is formed in the second printed circuit board 502. The second non-stripline transmission line 750-2 is implemented as a microstrip transmission line 750-2. The microstrip transmission line 750-2 includes a second non-stripline metal signal trace 770-2 that is formed in the second upper metal layer 760 and a second lower metal ground plane 620-2 that is formed in the second lower metallization layer 760. RF transmission line 700 also includes the metal signal trace connector 400, an RF shield 710, and the metal ground connector 420

RF shield 710 is similar to RF shield 510, but further includes a plurality of pins 714 that extend downwardly from the sidewalls thereof. These pins 714 extend through vias (not shown) in the dielectric substrate 520 to electrically connect to the second lower ground plane 620-2.

It will be appreciated that many modifications may be made to the above described embodiments without departing from the scope of the present invention.

Herein, references are made to one element such as a blind ground via “vertically overlapping” another element such as a transmission line segment. Such references to two “vertically overlapping” elements means that a vertical axis (i.e., an axis that extends perpendicularly to the multilayer printed circuit board structures according to embodiments of the present invention) extends through both elements.

Herein references are made to printed circuit boards. It will be appreciated that the term printed circuit board is used broadly to refer to a dielectric layer that has a metal layer (which may or may not be patterned) adhered to at least one major surface thereof.

The present invention has been described above with reference to the accompanying drawings. The invention is not limited to the illustrated embodiments; rather, these embodiments are intended to fully and completely disclose the invention to those skilled in this art. In the drawings, like numbers refer to like elements throughout. Thicknesses and dimensions of some elements may not be to scale.

Spatially relative terms, such as “under”, “below”, “lower”, “over”, “upper”, “top”, “bottom” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

Well-known functions or constructions may not be described in detail for brevity and/or clarity. As used herein the expression “and/or” includes any and all combinations of one or more of the associated listed items.

It will be appreciated that aspects of all embodiments disclosed herein may be combined in different ways to provide numerous additional embodiments. Thus, it will be appreciated that elements discussed above with respect to one specific embodiment may be incorporated into any of the other embodiments, either alone or in combination.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

1. A radio frequency (“RF”) transmission line, comprising:
a first printed circuit board that includes a first upper dielectric substrate, a first lower dielectric substrate, a first upper metal layer that is on an upper surface of the first upper dielectric substrate and including a first upper signal trace and a first upper ground plane, a first lower metal layer that is on a lower surface of the first lower dielectric substrate that forms a first lower ground plane, a first internal metal layer that is between the first upper dielectric substrate and the first lower dielectric substrate, the first internal metal layer including a first internal signal trace and a first internal ground plane;
a second printed circuit board that includes a second dielectric substrate and a second upper metal layer that is on an upper surface of the second dielectric substrate, the second upper metal layer including a second upper signal trace;
a metal signal trace connector that electrically connects the first upper signal trace to the second upper signal trace; and
an RF shielding cover that covers the metal signal trace connector.

2. (canceled)

3. The RF transmission line of claim 1, wherein the RF shielding cover is galvanically connected to the first upper ground plane.

4. The RF transmission line of claim 1, wherein the second upper metal layer further comprises a second upper ground plane, and the RF shielding cover is galvanically connected to the first upper ground plane and to the second upper ground plane.

5. The RF transmission line of claim 4, wherein the RF shielding cover, the first upper ground plane and the second upper ground plane substantially enclose the metal signal trace connector.

6-12. (canceled)

13. The RF transmission line of claim 1, wherein the second printed circuit board further includes a second lower metal layer that is on the lower surface of the second dielectric substrate that forms a second lower ground plane, and wherein the second upper signal trace and the second lower ground plane comprise the signal and ground conductors of a microstrip transmission line formed in the second printed circuit board.

14. The RF transmission line of claim 13, wherein the second dielectric substrate is thicker than the first upper dielectric substrate and is thicker than the first lower dielectric substrate.

15. The RF transmission line of claim 14, further comprising a metal ground connector that electrically connects the first lower ground plane to the second lower ground plane.

16. The RF transmission line of claim 1, wherein the second printed circuit board further includes a second lower metal layer that is on the lower surface of the second dielectric substrate that forms a second lower ground plane, wherein the second upper metal layer further comprises a second upper ground plane, and wherein the second upper signal trace comprises the signal conductor of a grounded coplanar waveguide transmission line that is formed in the second printed circuit board, and the second upper ground plane and the second lower ground plane comprise the ground conductor of the grounded coplanar waveguide transmission line.

17. (canceled)

18. The RF transmission line of claim 16, wherein the second dielectric substrate is thicker than the first upper dielectric substrate and is thicker than the first lower dielectric substrate.

19. The RF transmission line of claim 1, wherein the second upper metal layer further comprises a second upper ground plane, and wherein the second upper signal trace comprises the signal conductor of a coplanar waveguide transmission line that is formed in the second printed circuit board, and the second upper ground plane comprises the ground conductor of the coplanar waveguide transmission line.

20-21. (canceled)

22. The RF transmission line of claim 1, the first printed circuit board further comprising first and second rows of ground vias that extend through the first upper dielectric substrate and the first lower dielectric substrate, the first and second rows of ground vias electrically connecting the first upper ground plane, the first internal ground plane, and the first lower ground plane.

23. (canceled)

24. The RF transmission line of claim 1, wherein the first printed circuit board further comprising a first additional dielectric layer that is interposed between the first upper dielectric substrate and the first lower dielectric substrate.

25. The RF transmission line of claim 1, wherein the first upper ground plane surrounds the first upper signal trace on at least three sides.

26. A radio frequency (“RF”) transmission line, comprising:
a first printed circuit board that includes a first stripline transmission line and a first non-stripline transmission line that is electrically connected to the first stripline transmission line;
a second printed circuit board that includes a second stripline transmission line and a second non-stripline transmission line that is electrically connected to the second stripline transmission line;
a metal signal trace connector that electrically connects a first signal trace of the first non-stripline transmission line to a second signal trace of the second non-stripline transmission line; and
an RF shielding cover that covers the metal signal trace connector.

27. The RF transmission line of claim 26, wherein the first non-stripline transmission line comprises a microstrip transmission line, a coplanar waveguide transmission line, or a grounded coplanar waveguide transmission line.

28. The RF transmission line of claim 26, wherein the RF shielding cover comprises an upper surface and at least one sidewall extending downwardly from the upper surface.

29-30. (canceled)

31. The RF transmission line of claim 26, wherein the metal signal trace connector is a longitudinally extending metal strip that has a first end that galvanically connects to the first signal trace and a second end that galvanically connects to the second signal trace.

32. The RF transmission line of claim 26, wherein the metal signal trace connector is capacitively coupled to the first signal trace and to the second signal trace.

33. The RF transmission line of claim 26, wherein the first stripline transmission line includes a first upper ground plane and a first lower ground plane, and wherein the second stripline transmission line includes a second upper ground plane and a second lower ground plane.

34. The RF transmission line of claim 33, further comprising a metal ground connector that electrically connects the first lower ground plane to the second lower ground plane.

35-38. (canceled)
